(19) United States
(12) Patent Application Publication
(10) Pub. No.: US 2024/0219476 A1
(43) Pub. Date: Jul. 4, 2024

(54) Battery Life Prediction Apparatus and Operating Method Thereof

(71) Applicant: LG Energy Solution, Ltd., Seoul (KR)

(72) Inventors: Yeo Kyung Yoon, Daejeon (KR); Jeong Min Lee, Daejeon (KR)

(73) Assignees: LG Energy Solution, Ltd., Seoul (KR); LG Energy Solution, Ltd., Seoul (KR)

(21) Appl. No.: 18/288,264

(22) PCT Filed: Sep. 30, 2022
(86) PCT No.: PCT/KR2022/014848

§ 371 Date: Oct. 25, 2023

(30) Foreign Application Priority Data
Dec. 10, 2021 (KR) 10-2021-0176327

(51) Int. Cl. G01R 31/392; G01R 31/367; G01R 31/3835

(52) U.S. Cl. CPC G01R 31/392; G01R 31/3835; G01R 31/367

(57) ABSTRACT

A battery life prediction apparatus according to an embodiment disclosed herein includes a processor and memory having programmed thereon instructions that, when executed, are configured to cause the processor to obtain information about a charge end voltage of a battery corresponding to a charge protocol and predict a life of the battery corresponding to the charge protocol based on the information about the charge end voltage of the battery corresponding to the charge protocol.

### CROSS-REFERENCE TO RELATED APPLICATION

The present application is a national phase entry under 35 U.S.C. § 371 of International Application No. PCT/KR2022/014848 filed Sep. 30, 2022, which claims priority from Korean Patent Application No. 10-2021-0176327 filed Dec. 10, 2021, all of which are incorporated herein by reference.

### TECHNICAL FIELD

Embodiments disclosed herein relate to a battery life prediction apparatus and an operating method thereof.

### BACKGROUND ART

Recently, research and development of secondary batteries have been actively performed. Herein, the secondary batteries, which are chargeable/dischargeable batteries, may include all of conventional nickel (Ni)/cadmium (Cd) batteries, Ni/metal hydride (MH) batteries, etc., and recent lithium-ion batteries. Among the secondary batteries, a lithium-ion battery has a much higher energy density than those of the conventional Ni/Cd batteries, Ni/MH batteries, etc. Moreover, the lithium-ion battery may be manufactured to be small and lightweight, such that the lithium-ion battery has been used as a power source of mobile devices, and recently, a use range thereof has been extended to power sources for electric vehicles, attracting attention as next-generation energy storage media.

Recent batteries have a fast charging function. A fast charge time is proportional to the cycle life of the battery, such that the cycle life of the battery may be shortened as the fast charge time is reduced. Thus, it may be important to predict the cycle life of the battery with respect to a charge protocol. Due to the nature of the cycle life of the battery, a long-term test needs to be conducted, and thus there is a need for a method for predicting the cycle life of the battery based on an initial cycle.

### SUMMARY

### Technical Problem

Embodiments disclosed herein aim to provide a battery life prediction apparatus and an operating method thereof in which a cycle life of a battery may be predicted when the battery is charged according to a charge protocol.

Embodiments disclosed herein aim to provide a battery life prediction apparatus and an operating method thereof in which a cycle life of a battery may be predicted based on an initial cycle of the battery corresponding to a charge protocol.

Embodiments disclosed herein aim to provide a battery life prediction apparatus and an operating method thereof in which a life of the battery may be predicted when a fast charging protocol is used where prediction of the cycle life of the battery is impossible based on an existing capacity retention state.

Technical problems of the embodiments disclosed herein are not limited to the above-described technical problems, and other unmentioned technical problems would be clearly understood by one of ordinary skill in the art from the following description.

### Technical Solution

A battery life prediction apparatus according to an embodiment disclosed herein includes a processor and memory having programmed thereon instructions that, when executed, are configured to cause the processor to obtain information about a charge end voltage of a battery corresponding to a charge protocol and predict a life of the battery corresponding to the charge protocol based on the information about the charge end voltage of the battery corresponding to the charge protocol.

In an embodiment, the instructions may be further configured to cause the processor to linearly fit the charge end voltage of the battery corresponding to the charge protocol in every charge cycle of the battery.

In an embodiment, the instructions may be further configured to cause the processor to predict the life of the battery as a cycle in which the drive end voltage is reached based on the linear fit.

In an embodiment, the drive end voltage may be about 4.2 V.

In an embodiment, the instructions may be further configured to cause the processor to select a section in the charge cycle of the battery and linearly fit the charge end voltage of the battery in the selected section.

In an embodiment, the selected section may correspond to between a 100th cycle of the battery and a 200th cycle of the battery.

In an embodiment, the instructions may be configured to cause the processor to predict a number of cycles in which the battery may be charged.

In an embodiment, the instructions may be further configured to cause the processor to compare a plurality of predicted lifetimes of the battery when the battery is charged based on a plurality of charge protocols.

In an embodiment, the instructions may be further configured to cause the processor to compare the plurality of charge protocols based on the respective predicted lifetimes of the battery corresponding to each of the plurality of charge protocols.

In an embodiment, the charge protocol may comprise information about a current that charges the battery according to a step based on an amount of time required for charging the battery.

An operating method of a battery life prediction apparatus according to an embodiment disclosed herein includes obtaining, by a processor, information about a charge end voltage of a battery corresponding to a charge protocol and predicting, by the processor, a life of the battery corresponding to the charge protocol based on the information about the charge end voltage of the battery corresponding to the charge protocol.

In an embodiment, predicting, by the processor, the life of the battery may include linearly fitting the charge end voltage of the battery corresponding to the charge protocol in every charge cycle of the battery.

In an embodiment, predicting, by the processor, the life of the battery may be predicted as a cycle in which a drive end voltage is reached based on the linear fit.

In an embodiment, predicting, by the processor, the life of the battery further include selecting a section in the charge cycle of the battery and linearly fitting the charge end voltage of the battery in the selected section.

In an embodiment, the selected section corresponds to between a 100^{th} cycle of the battery and a 200^{th} cycle of the battery.

### Advantageous Effects

A battery life prediction apparatus and an operating method thereof according to an embodiment disclosed herein may predict a cycle life of a battery according to each charge protocol.

A battery life prediction apparatus and an operating method thereof according to an embodiment disclosed herein may predict a cycle life of a battery based on an initial cycle when the battery is charged according to a charge protocol.

A battery life prediction apparatus and an operating method thereof according to an embodiment disclosed herein may predict a life of a battery by linearly fitting a charge end voltage according to a charge cycle of the battery.

Moreover, various effects recognized directly or indirectly from the disclosure may be provided.

### BRIEF DESCRIPTION OF THE DRAWINGS

FIG. 1 is a block diagram of a battery life prediction apparatus according to an embodiment disclosed herein.

FIG. 2 shows a charge end voltage of a battery according to an embodiment disclosed herein.

FIG. 3 is a flowchart of an operating method of a battery life prediction apparatus according to an embodiment disclosed herein.

FIGS. 4 and 5 are flowcharts of an operating method of a battery life prediction apparatus according to an embodiment disclosed herein.

FIG. 6 is a block diagram showing a hardware configuration of a computing system for performing an operating method of a battery life prediction apparatus, according to an embodiment disclosed herein.

### DETAILED DESCRIPTION

Hereinafter, embodiments disclosed in this document will be described in detail with reference to the exemplary drawings. In adding reference numerals to components of each drawing, it should be noted that the same components are given the same reference numerals even though they are indicated in different drawings. In addition, in describing the embodiments disclosed in this document, when it is determined that a detailed description of a related known configuration or function interferes with the understanding of an embodiment disclosed in this document, the detailed description thereof will be omitted.

To describe a component of an embodiment disclosed herein, terms such as first, second, A, B, (a), (b), etc., may be used. These terms are used merely for distinguishing one component from another component and do not limit the component to the essence, sequence, order, etc., of the component. The terms used herein, including technical and scientific terms, have the same meanings as terms that are generally understood by those skilled in the art, as long as the terms are not differently defined. Generally, the terms defined in a generally used dictionary should be interpreted as having the same meanings as the contextual meanings of the relevant technology and should not be interpreted as having ideal or exaggerated meanings unless they are clearly defined in the present application.

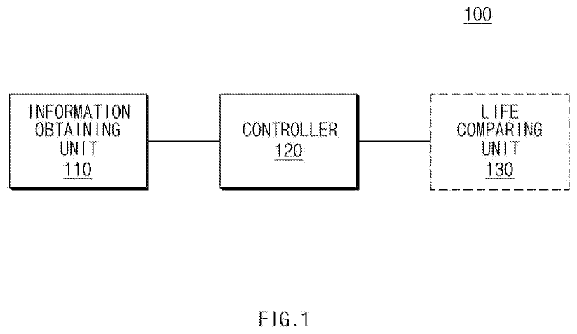

FIG. 1 is a block diagram of a battery life prediction apparatus according to an embodiment disclosed herein.

Referring to FIG. 1, a battery life prediction apparatus 100 according to an embodiment disclosed herein may include an information obtaining unit 110 and a controller 120. According to an embodiment, the battery life prediction apparatus 100 may further include a life comparing unit 130.

The information obtaining unit 110 may obtain information about a charge end voltage of the battery corresponding to a charge protocol. For example, the information obtaining unit 110 may obtain the information about the charge end voltage of the battery in every charge cycle when the battery is charged based on the charge protocol.

In an embodiment, the charge protocol may be configured with information about a current that charges the battery according to a step based on a time required for charging the battery. For example, the charge protocol may be configured with a C-rate per depth of charge of the battery. In this case, C-rate may mean the degree of a current to which a battery cell is charged for each step.

The controller 120 may predict the life of the battery corresponding to the charge protocol based on the information about the charge end voltage of the battery corresponding to the charge protocol. For example, the controller 120 may predict the cycle life of the battery corresponding to the charge protocol. In an embodiment, the controller 120 may predict the number of cycles in which the battery may be charged according to the charge protocol.

The controller 120 may linearly fit the charge end voltage of the battery corresponding to the charge protocol in every charge cycle of the battery. For example, the controller 120 may obtain the charge end voltage of the battery from the information obtaining unit 110 in every charge cycle, and fit each charge end voltage to a graph. In another example, the controller 120 may fit the charge end voltage per charge cycle of the battery to a graph of y=ax+b. In an embodiment, y may correspond to the charge end voltage of the battery, x may correspond to the charge cycle of the battery, a may correspond to a change rate of the charge end voltage of the battery per charge cycle, and b may correspond to the charge end voltage of the battery in a first charge cycle.

The controller 120 may predict a cycle in which the drive end voltage is reached as the life of the battery based on the linearly fitted graph. For example, the drive end voltage may be a voltage in which it is not possible to fast charge the battery any longer. In another example, the drive end voltage may be set to about 4.2 V. In another example, the controller 120 may calculate a cycle in which y reaches the drive end voltage in the graph y=ax+b that linearly fits the charge end voltage, and may predict the cycle as the life of the battery.

According to an embodiment, the controller 120 may select a specific section in the charge cycle of the battery. When the specific section is selected, the controller 120 may linearly fit the charge end voltage of the battery in the specific section. In this case, the controller 120 may linearly fit the charge end voltage per charge cycle of the battery to the graph y=ax+b. In an embodiment, the specific section may be a section corresponding to 100 cycles to 200 cycles. However, the disclosure is not limited thereto, and the particular section may be a cycle corresponding to n to m cycles, in which both n and m may be natural numbers and m is greater than n. In an embodiment, the controller 120 may calculate a cycle in which the drive end voltage is reached based on the graph that linearly fits the charge end voltage of the battery in the specific section, and the cycle may be predicted as the cycle life of the battery.

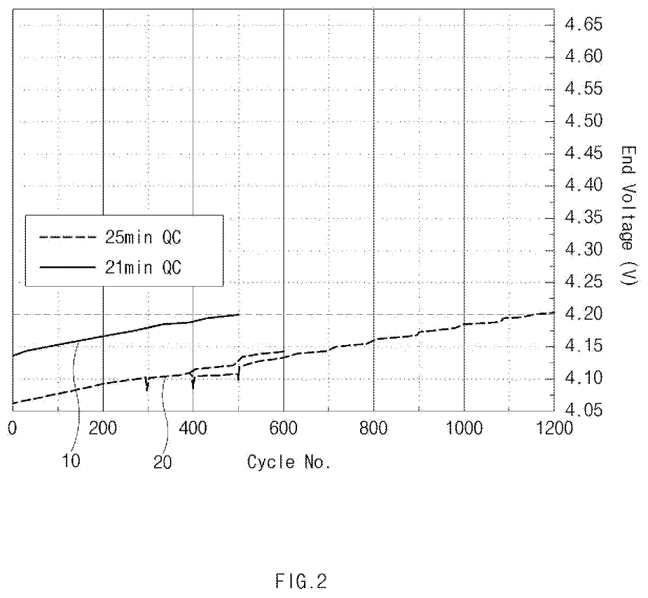

FIG. 2 shows a charge end voltage of a battery according to an embodiment disclosed herein.

Referring to FIG. 2, it may be seen that a charge end voltage 10 of a 21-minute-charge protocol is formed in a higher section than a charge end voltage 20 of a 25-minute charge protocol. As a result of linearly fitting the charge end voltage 10 of the 21-minute charge protocol, a change rate is similar to that of the charge end voltage 20 of the 25-minute charge protocol, but the charge end voltage is formed higher in a first cycle. The charging time is absolutely shortened, such that the charge end voltage of the 21-minute charge protocol is higher than the charge end voltage of the 25-minute charge protocol in the first cycle. Moreover, the change rate of the charge end voltage 10 of the 21-minute charge protocol and the change rate of the charge end voltage 20 of the 25-minute charge protocol are similar to each other because the charge protocols are merely changed for the same battery and thus a charge transfer resistance and a diffusion resistance are similar.

Moreover, the battery life prediction apparatus 100 may determine a cycle where the charge end voltage 10 of the 21-minute charge protocol reaches the drive end voltage of 4.2 V as 500 charge cycles. That is, when the battery is charged based on the 21-minute charge protocol, the charge cycle life of the battery may be determined as 500 times.

Moreover, the battery life prediction apparatus 100 may determine a cycle where the charge end voltage 20 of the 25-minute charge protocol reaches the drive end voltage of 4.2 V as 1200 charge cycles. That is, when the battery is charged based on the 25-minute charge protocol, the charge cycle life of the battery may be determined as 1200 times.

The battery life prediction apparatus 100 may determine the cycle life of the battery based on the initial charge cycle of the battery, such that the time for determining the cycle life of the battery may be saved and the cycle life of the battery may be more accurately determined.

Referring to FIG. 1, the battery life prediction apparatus 100 according to an embodiment disclosed herein may further include the life comparing unit 130.

The life comparing unit 130 may compare the lives of the battery when the battery is charged based on a plurality of charge protocols. For example, the cycle life of the battery corresponding to a case where the battery is charged using the 21-minute charge protocol may be compared with the cycle life of the battery corresponding to a case where the battery is charged using the 25-minute charge protocol.

In an embodiment, the life comparing unit 130 may compare the plurality of charge protocols based on a predicted life of the battery corresponding to each of the plurality of charge protocols.

In an embodiment, the life comparing unit 130 may determine a charge protocol having a corresponding charge cycle life according to the number of charge cycles set by a user. In this case, the life comparing unit 130 may guide the corresponding charge protocol to the user.

The battery life prediction apparatus according to an embodiment disclosed herein may predict a cycle life of a battery according to each charge protocol.

The battery life prediction apparatus according to an embodiment disclosed herein may predict a cycle life of a battery based on an initial cycle when the battery is charged according to a charge protocol.

The battery life prediction apparatus according to an embodiment disclosed herein may predict a life of a battery by linearly fitting a charge end voltage according to a charge cycle of the battery.

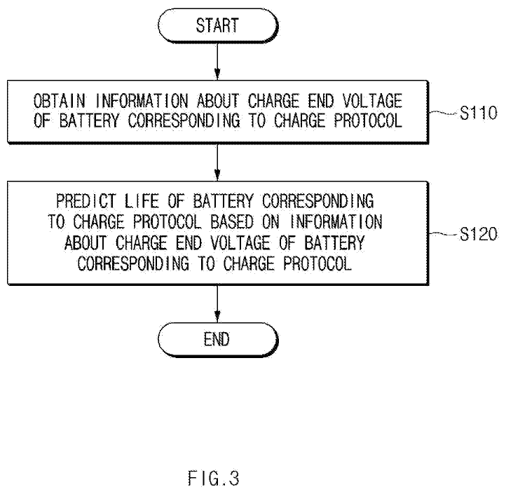

FIG. 3 is a flowchart of an operating method of a battery life prediction apparatus according to an embodiment disclosed herein.

Referring to FIG. 3, the operating method of the battery life prediction apparatus 100 according to an embodiment disclosed herein includes operation S110 of obtaining information about a charge end voltage of a battery corresponding to a charge protocol and operation S120 of predicting a life of the battery corresponding to the charge protocol based on information about the charge end voltage of the battery corresponding to the charge protocol.

In operation S110 of obtaining the information about the charge end voltage of the battery corresponding to the charge protocol, the information obtaining unit 110 may obtain the information about the charge end voltage of the battery corresponding to the charge protocol. For example, the information obtaining unit 110 may obtain the information about the charge end voltage of the battery corresponding to the charge protocol for each charge cycle of the battery. The information obtaining unit 110 may transmit the obtained information about the charge end voltage to the controller 120.

In operation S120 of predicting the life of the battery corresponding to the charge protocol based on the information about the charge end voltage of the battery corresponding to the charge protocol, the controller 120 may predict the life of the battery corresponding to the charge protocol based on the information about the charge end voltage of the battery corresponding to the charge protocol. For example, the controller 120 may predict the charge cycle life of the battery based on the information about the charge end voltage of the battery.

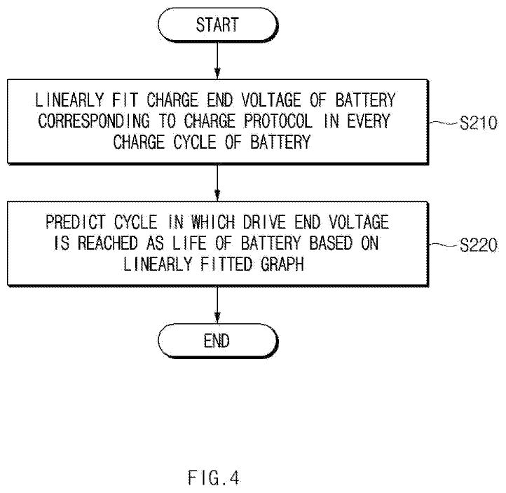

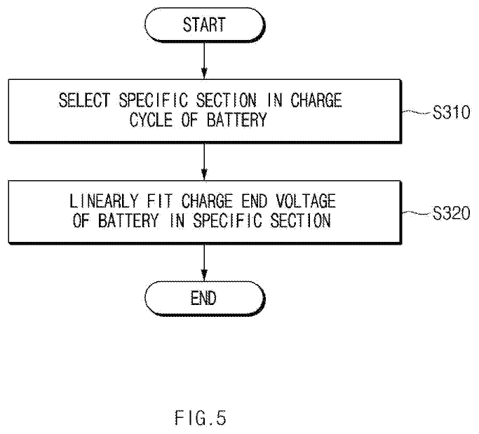

FIGS. 4 and 5 are flowcharts of an operating method of a battery life prediction apparatus according to an embodiment disclosed herein.

Referring to FIG. 4, the operating method includes operation S210 of linearly fitting the charge end voltage of the battery corresponding to the charge protocol for each charge cycle of the battery and operation S220 of predicting a cycle in which a drive end voltage is reached as the life of the battery based on the linearly fitted graph. According to an embodiment, operations S210 and S220 may be included in operation S120 of FIG. 3.

In operation S210 of linearly fitting the charge end voltage of the battery corresponding to the charge protocol for each charge cycle of the battery, the controller 120 may linearly fit the charge end voltage of the battery corresponding to the charge protocol for each charge cycle of the battery. For example, the controller 120 may linearly fit the charge end voltage of the battery to the graph y=ax+b. In an embodiment, y may correspond to the charge end voltage of the battery, x may correspond to the charge cycle of the battery, a may correspond to a change rate of the charge end voltage of the battery per charge cycle, and b may correspond to the charge end voltage of the battery in a first charge cycle.

In operation S220 of predicting the cycle in which the drive end voltage is reached as the life of the battery based on the linearly fitted graph, the controller 120 may predict the cycle in which the charge end voltage reaches the drive end voltage as the life of the battery based on the linearly fitted graph. For example, the controller 120 may predict the cycle in which the charge end voltage reaches the drive end voltage as the charge cycle life of the battery. In an embodiment, the drive end voltage may be about 4.2 V.

Referring to FIG. 5, the operating method includes operation S310 of selecting a particular section of the charge cycle of the battery and operation S320 of linearly fitting the charge end voltage of the battery in the particular section. According to an embodiment, operations S310 and S320 may be included in operation S120 of FIG. 3.

In operation S310 of selecting the particular section in the charge cycle of the battery, the controller 120 may select a specific section in the charge cycle of the battery. For example, the specific section may be a section corresponding to 100 cycles to 200 cycles. However, the disclosure is not limited thereto, and the particular section may be a cycle corresponding to n to m cycles, in which both n and m may be natural numbers and m is greater than n.

When the specific section is selected, in operation S320 of linearly fitting the charge end voltage of the battery in the specific section, the controller 120 may linearly fit the charge end voltage of the battery in the specific section. For example, the controller 120 may linearly fit the charge end voltage per charge cycle of the battery to the graph y=ax+b. In an embodiment, the controller 120 may calculate a cycle in which the drive end voltage is reached based on the graph that linearly fits the charge end voltage of the battery in the specific section, and the cycle may be predicted as the cycle life of the battery.

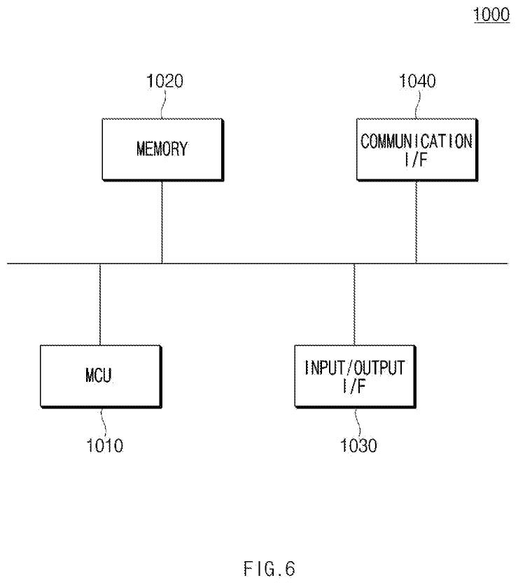

FIG. 6 is a block diagram showing a hardware configuration of a computing system for performing an operating method of a battery life prediction apparatus, according to an embodiment disclosed herein.

Referring to FIG. 6, a computing system 1000 according to an embodiment disclosed herein may include an MCU 1010, a memory 1020, an input/output I/F 1030, and a communication I/F 1040.

The MCU 1010 may be a processor that executes various programs (e.g., a battery pack voltage or current collection program, a relay control program included in a battery pack, an internal resistance calculation program, etc.) stored in the memory 1020, processes various information including a charge end voltage and a drive end voltage of a battery through these programs, and executes the above-described functions of the battery life prediction apparatus shown in FIG. 1.

The memory 1020 may store various programs regarding log information collection and diagnosis of the battery, etc. The memory 1020 may also store various information such as a current, a voltage, a charge end voltage, a drive end voltage, charge protocol information, etc., of the battery.

The memory 1020 may be provided in plural, depending on a need. The memory 1020 may be volatile memory or non-volatile memory. For the memory 1020 as the volatile memory, random access memory (RAM), dynamic RAM (DRAM), static RAM (SRAM), etc., may be used. For the memory 1020 as the nonvolatile memory, read only memory (ROM), programmable ROM (PROM), electrically alterable ROM (EAROM), erasable PROM (EPROM), electrically erasable PROM (EEPROM), flash memory, etc., may be used. The above-listed examples of the memory 1020 are merely examples and are not limited thereto.

The input/output I/F 1030 may provide an interface for transmitting and receiving data by connecting an input device (not shown) such as a keyboard, a mouse, a touch panel, etc., and an output device such as a display (not shown), etc., to the MCU 1010.

The communication I/F 1040, which is a component capable of transmitting and receiving various data to and from a server, may be various devices capable of supporting wired or wireless communication. For example, the battery life prediction apparatus may transmit and receive a relay control program included in a battery pack or information such as a current or a charge end voltage of various battery packs from an external server separately provided through the communication I/F 1040.

As such, a computer program according to an embodiment disclosed herein may be recorded in the memory 1020 and processed by the MCU 1010, thus being implemented as a module that performs functions shown in FIG. 1.

The above description is merely illustrative of the technical idea of the present disclosure, and various modifications and variations will be possible without departing from the essential characteristics of embodiments of the present disclosure by those of ordinary skill in the art to which the embodiments disclosed herein pertains.

Therefore, the embodiments disclosed herein are intended for description rather than limitation of the technical spirit of the embodiments disclosed herein and the scope of the technical spirit of the present disclosure is not limited by these embodiments disclosed herein. The protection scope of the technical spirit disclosed herein should be interpreted by the following claims, and all technical spirits within the same range should be understood to be included in the range of the present disclosure.

1. A battery life prediction apparatus comprising:
a processor; and
memory having programmed thereon instructions that, when executed, are configured to cause the processor to:
obtain information about a charge end voltage of a battery corresponding to a charge protocol; and
predict a life of the battery corresponding to the charge protocol based on the information about the charge end voltage of the battery corresponding to the charge protocol.

2. The battery life prediction apparatus of claim 1, wherein the instructions are further configured to cause the processor to linearly fit the charge end voltage of the battery corresponding to the charge protocol in every charge cycle of the battery.

3. The battery life prediction apparatus of claim 2, wherein the instructions are further configured to cause the processor to predict the life of the battery as a cycle in which a drive end voltage is reached based on the linear fit.

4. The battery life prediction apparatus of claim 3, wherein the drive end voltage is 4.2 V.

5. The battery life prediction apparatus of claim 2, wherein the instructions are further configured to cause the processor to select a section in the charge cycle of the battery and linearly fit the charge end voltage of the battery in the selected section.

6. The battery life prediction apparatus of claim 5, wherein the selected section corresponds to between a 100^{th} cycle of the battery and a 200^{th} cycle of the battery.

7. The battery life prediction apparatus of claim 1, wherein the instructions are further configured to cause the processor to predict a number of cycles in which the battery is chargeable.

8. The battery life prediction apparatus of claim 1, wherein the instructions are further configured to cause the processor to compare a plurality of predicted lifetimes of the battery when the battery is charged based on a plurality of charge protocols.

9. The battery life prediction apparatus of claim 8, wherein the instructions are further configured to cause the processor to compare the plurality of charge protocols based on the respective predicted lifetimes of the battery corresponding to each of the plurality of charge protocols.

10. The battery life prediction apparatus of claim 1, wherein the charge protocol comprises information about a current charging the battery according to a step based on an amount of time required for charging the battery.

11. An operating method of a battery life prediction apparatus, the operating method comprising:
obtaining, by a processor, information about a charge end voltage of a battery corresponding to a charge protocol; and
predicting, by the processor, a life of the battery corresponding to the charge protocol based on the information about the charge end voltage of the battery corresponding to the charge protocol.

12. The operating method of claim 11, wherein the predicting of the life of the battery comprises linearly fitting the charge end voltage of the battery corresponding to the charge protocol in every charge cycle of the battery.

13. The operating method of claim 12, wherein of the life of the battery is predicted as a cycle in which a drive end voltage is reached based on the linear fit.

14. The operating method of claim 11, wherein predicting the life of the battery further comprises:
selecting a section in a charge cycle of the battery; and
linearly fitting the charge end voltage of the battery in the selected section.

15. The operating method of claim 14, wherein the selected section corresponds to between a 100^{th} cycle of the battery and a 200^{th} cycle of the battery.
